(19) United States
(12) Patent Application Publication
(10) Pub. No.: US 2026/0113011 A1
(43) Pub. Date: Apr. 23, 2026

(54) ADAPTIVE EQUALIZER CIRCUIT AND OPERATION METHOD THEREOF

(71) Applicant: ASMedia Technology Inc., New Taipei City (TW)

(72) Inventors: Chieh-Jui Ho, New Taipei City (TW); Yu-Chuan Lin, New Taipei City (TW)

(73) Assignee: ASMedia Technology Inc., New Taipei City (TW)

(21) Appl. No.: 19/074,480

(22) Filed: Mar. 10, 2025

(30) Foreign Application Priority Data
Oct. 17, 2024 (TW) 113139518

(51) Int. Cl. H03G 5/16; H03F 3/04; H03G 3/30

(52) U.S. Cl. CPC H03G 5/165; H03F 3/04; H03G 3/30; H03G 2201/103

(57) ABSTRACT

An adaptive equalizer circuit and an operation method thereof are provided. The adaptive equalizer circuit includes an amplifier circuit and an adaptive circuit. The amplifier circuit is coupled to the adaptive circuit. The amplifier circuit receives an input signal. The amplifier circuit provides a compensation signal to the adaptive circuit based on the input signal. The adaptive circuit provides a compensation setting value and a feedback signal to the amplifier circuit based on the compensation signal. A low-frequency response and a high-frequency gain of the amplifier circuit are adjusted based on the compensation setting value and the feedback signal respectively.

### CROSS-REFERENCE TO RELATED APPLICATION

This application claims the priority benefit of Taiwan application serial no. 113139518, filed on Oct. 17, 2024. The entirety of the above-mentioned patent application is hereby incorporated by reference herein and made a part of this specification.

### BACKGROUND

### Technical Field

The disclosure relates to an equalizer circuit, and particularly relates to an adaptive equalizer circuit and an operation method thereof.

### Description of Related Art

In a condition of high-speed transmission, a high-frequency component of a signal suffer severe loss. In a conventional receiver, there is an independent low-frequency feedback circuit and an adaptive circuit to perform compensation for the high-frequency component and the low-frequency component of the signal. Specifically, the low-frequency feedback circuit may make the compensation result more uniform, while the adaptive circuit may enable the equalizer of the receiver to adapt to signals with different degrees of loss.

However, the independent low-frequency feedback circuit and adaptive circuit may increase the power consumption of the receiver, and both of these circuits include low pass filters which occupy a large circuit area.

### SUMMARY

In view of this, the disclosure provides an adaptive equalizer circuit and an operation method thereof, which can save power consumption and reduce a circuit area.

An adaptive equalizer circuit of the disclosure includes an amplifier circuit and an adaptive circuit. The amplifier circuit is coupled to the adaptive circuit. The amplifier circuit receives an input signal. The amplifier circuit provides a compensation signal to the adaptive circuit based on the input signal. The adaptive circuit provides a compensation setting value and a feedback signal to the amplifier circuit based on the compensation signal. A low-frequency response and a high-frequency gain of the amplifier circuit are adjusted based on the feedback signal and the compensation setting value respectively.

An operation method of an adaptive equalizer circuit of the disclosure includes: receiving an input signal by the amplifier circuit; providing a compensation signal to the adaptive circuit based on the input signal by the amplifier circuit; and providing a compensation setting value and a feedback signal to the amplifier circuit based on the compensation signal by the adaptive circuit. A low-frequency response and a high-frequency gain of the amplifier circuit are adjusted based on the feedback signal and the compensation setting value respectively.

Based on the above, the adaptive equalizer circuit and the operation method provided by the disclosure may perform compensation on the input signal to provide an output signal with a proportion of a high-frequency component and a low-frequency component tending to be consistent, and adjust the low-frequency response and the high-frequency gain of the amplifier circuit based on the compensation signal, to effectively enhance the compensation capability for the input signal.

To make the above-mentioned features and advantages of the disclosure more comprehensible, embodiments are described in detail below with reference to the accompanying drawings.

### BRIEF DESCRIPTION OF THE DRAWINGS

FIG. 1 illustrates a schematic diagram of an adaptive equalizer circuit according to an embodiment of the disclosure.

FIG. 2 illustrates a schematic diagram of an adaptive equalizer circuit according to the first embodiment of the disclosure.

FIG. 3 illustrates a circuit diagram of an amplifier circuit, a buffer, and a low pass filter according to the first embodiment of the disclosure.

FIG. 4 illustrates a schematic diagram of an adaptive equalizer circuit according to the second embodiment of the disclosure.

FIG. 5 illustrates a flowchart of an operation method of an adaptive equalizer circuit according to an embodiment of the disclosure.

### DESCRIPTION OF THE EMBODIMENTS

Some embodiments of the disclosure are described in detail below with reference to the accompanying drawings. When appearing in different drawings, the same reference numerals are regarded as the same or similar elements. These embodiments are only a part of the disclosure and do not disclose all possible implementations of the disclosure. More precisely, these embodiments are only examples within the scope of the patent claims of the disclosure.

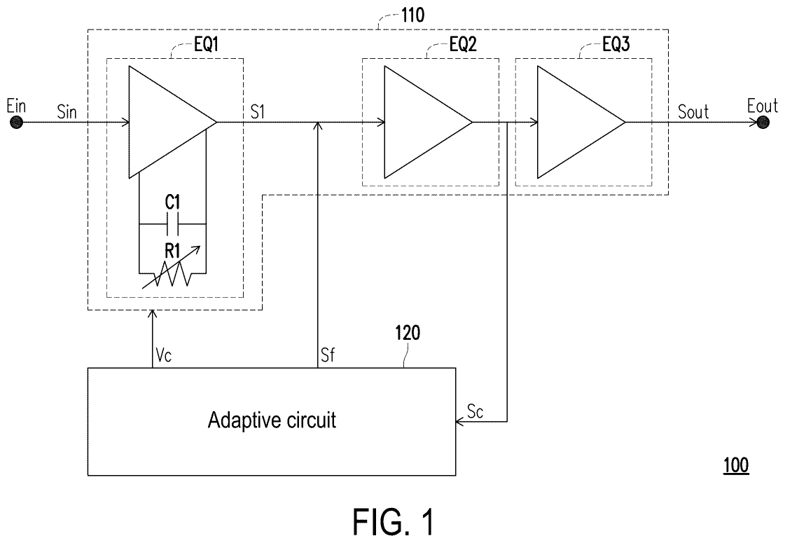

FIG. 1 illustrates a schematic diagram of an adaptive equalizer circuit according to an embodiment of the disclosure. With reference to FIG. 1, an adaptive equalizer circuit 100 includes an input terminal Ein, an amplifier circuit 110, an adaptive circuit 120, and an output terminal Eout. The amplifier circuit 110 is coupled to the adaptive circuit 120, and the amplifier circuit 110 is coupled between the input terminal Ein and the output terminal Eout. In this embodiment, the amplifier circuit 110 includes amplifiers EQ1 to EQ3. The amplifier EQ1 is coupled between the input terminal Ein and the amplifier EQ2. The amplifier EQ2 is coupled between the amplifier EQ1 and the amplifier EQ3. The amplifier EQ3 is coupled between the amplifier EQ2 and the output terminal Eout. In this embodiment, the amplifier EQ1 is a linear equalizing amplifier including a capacitor C1 and a variable resistor R1. In this embodiment, the amplifiers EQ2 and EQ3 are buffer amplifiers.

In this embodiment, the amplifier circuit 110 may be configured to receive an input signal Sin. Specifically, the amplifier EQ1 of the amplifier circuit 110 may receive the input signal Sin from the input terminal Ein. The input signal Sin is, for example, a high-speed transmission signal.

The amplifier circuit 110 may provide a compensation signal Sc to the adaptive circuit 120 based on the input signal Sin. Specifically, the amplifier EQ1 may perform high-frequency compensation on the input signal Sin to enhance the high-frequency component of the input signal Sin, thereby generating a signal S1. Next, the amplifier EQ2 of the amplifier circuit 110 may perform low-frequency compensation on the signal S1 to make the high-frequency component and the low-frequency component of the signal S1 more uniform (that is, to make a proportion of the high-frequency component and the low-frequency component of the signal S1 tend to be consistent), thereby generating the compensation signal Sc, and providing the compensation signal Sc to the adaptive circuit 120.

The adaptive circuit 120 may provide a compensation setting value Vc and a feedback signal Sf to the amplifier circuit 110 based on the compensation signal Sc. The low-frequency response and the high-frequency gain of the amplifier circuit 110 are adjusted based on the feedback signal Sf and the compensation setting value Vc, respectively. Specifically, the amplifier EQ1 of the amplifier circuit 110 receives the compensation setting value Vc from the adaptive circuit 120, and the high-frequency gain of the amplifier EQ1 is adjusted based on the compensation setting value Vc to adapt to different input signals Sin. Additionally, the amplifier EQ2 of the amplifier circuit 110 receives the feedback signal Sf from the adaptive circuit 120, and the low-frequency response of the amplifier EQ2 is adjusted based on the feedback signal Sf. In another aspect, the amplifier EQ3 may provide an output signal Sout to the output terminal Eout based on the compensation signal Sc.

According to the above, the amplifier circuit 110 may compensate for the input signal Sin to provide an output signal Sout with a proportion of a high-frequency component and a low-frequency component tending to be consistent. Additionally, the adaptive circuit 120 may provide the compensation setting value Vc and the feedback signal Sf to the amplifier circuit 110 based on the compensation signal Sc, to adjust the low-frequency response and the high-frequency gain of the amplifier circuit 110, thereby enhancing the compensation capability for the input signal Sin.

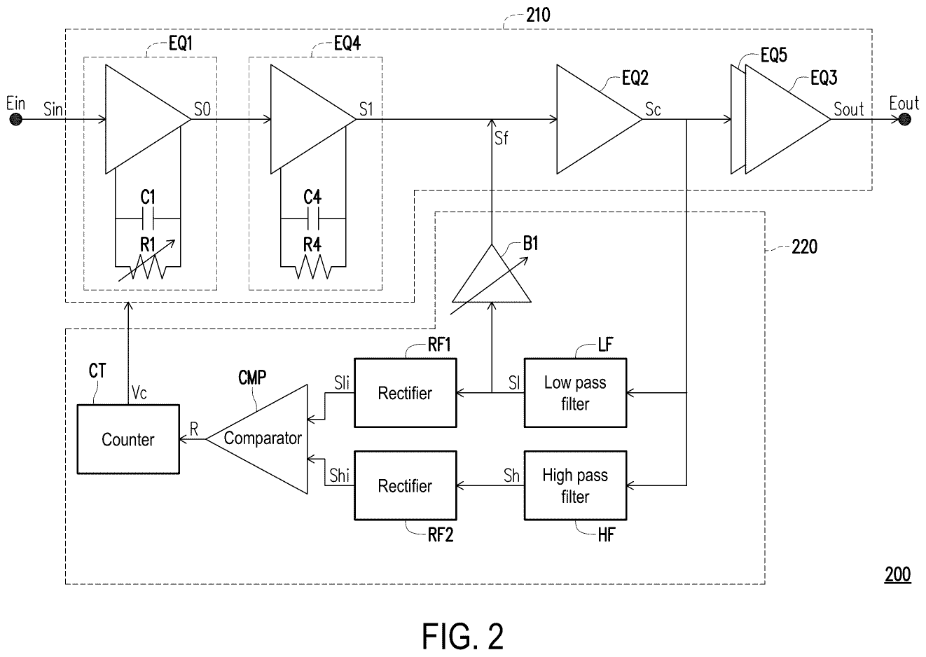

FIG. 2 illustrates a schematic diagram of an adaptive equalizer circuit according to the first embodiment of the disclosure. Please refer to FIG. 2. In this embodiment, an adaptive equalizer circuit 200 includes an input terminal Ein, an amplifier circuit 210, an adaptive circuit 220, and an output terminal Eout. The amplifier circuit 210 includes amplifiers EQ1 to EQ5. The amplifier EQ1 is a linear equalizing amplifier including a capacitor C1 and a variable resistor R1, and the amplifier EQ4 is a linear equalizing amplifier including a capacitor C4 and a resistor R4. The amplifiers EQ2, EQ3, and EQ5 are buffer amplifiers. Although the number of the amplifier EQ4 (or the amplifier EQ5) shown in FIG. 2 is one, the number of the amplifier EQ4 (or the amplifier EQ5) may be designed according to actual requirements, and the disclosure does not impose any limitations.

The adaptive circuit 220 includes a low pass filter LF, a high pass filter HF, a rectifier RF1, a rectifier RF2, a comparator CMP, a counter CT, and a buffer B1. The low pass filter LF is coupled to the amplifier EQ2. The high pass filter HF is coupled to the amplifier EQ2. The rectifier RF1 is coupled to the low pass filter LF. The rectifier RF2 is coupled to the high pass filter HF. The comparator CMP is coupled to the rectifier RF1 and the rectifier RF2. The counter CT is coupled to the comparator CMP. The buffer B1 is coupled to the low pass filter LF.

In this embodiment, the low pass filter LF, the high pass filter HF, the rectifier RF1, the rectifier RF2, the comparator CMP, the counter CT, and the buffer B1 may be, for example, any programmable digital circuits well-known to persons skilled in the art.

In this embodiment, the adaptive circuit 220 may include a low-frequency feedback loop and an adaptation loop. The low-frequency feedback loop is composed of the low pass filter LF and the buffer B1, and the adaptation loop is composed of the low pass filter LF, the high pass filter HF, the rectifier RF1, the rectifier RF2, the comparator CMP, and the counter CT. In this embodiment, the low-frequency feedback loop and the adaptation loop share one low pass filter LF, which may reduce the power consumption of the adaptive equalizer circuit 200 and save a circuit area of the adaptive equalizer circuit 200.

In this embodiment, the amplifier EQ1 receives an input signal Sin from the input terminal Ein. The input signal Sin is, for example, a high-speed transmission signal with severe high-frequency component loss. The amplifier EQ1 may perform the high-frequency compensation on the input signal Sin to generate a signal S0, and the amplifier EQ4 may perform high-frequency compensation on the signal S0 to generate a signal S1. Subsequently, the amplifier EQ2 may perform the low-frequency compensation on the signal S1 to make the high-frequency component and the low-frequency component of the signal S1 more uniform, thereby generating a compensation signal Sc.

The amplifier EQ2 may output the compensation signal Sc to the amplifier EQ5. Accordingly, the amplifier EQ5 and the amplifier EQ3 may provide an output signal Sout to the output terminal Eout based on the compensation signal Sc with a proportion of the high-frequency component and the low-frequency component tending to be consistent.

In another aspect, the amplifier EQ2 may provide the compensation signal Sc to the low-frequency feedback loop and the adaptation loop of the adaptive circuit 220, to enhance the compensation capability of the adaptive equalizer circuit 200. Specifically, the amplifier EQ2 may provide the compensation signal Sc to the low pass filter LF and the high pass filter HF of the adaptive circuit 220.

Regarding the low-frequency feedback loop, the low pass filter LF may extract the low-frequency component from the compensation signal Sc, thereby generating a low-frequency component signal Sl. Subsequently, the low pass filter LF may provide the low-frequency component signal Sl to the buffer B1. Accordingly, the buffer B1 may provide a feedback signal Sf to the amplifier EQ2 based on the low-frequency component signal Sl, to adjust the low-frequency response of the amplifier EQ2.

Regarding the adaptation loop, the low pass filter LF may extract the low-frequency component from the compensation signal Sc to generate a low-frequency component signal Sl, and provide the low-frequency component signal Sl to the rectifier RF1. The rectifier RF1 may generate a low-frequency intensity signal Sli based on the low-frequency component signal Sl, and provide the low-frequency intensity signal Sli to the comparator CMP. Similarly, the high pass filter HF may extract the high-frequency component from the compensation signal Sc to generate a high-frequency component signal Sh, and provide the high-frequency component signal Sh to the rectifier RF2. The rectifier RF2 may generate a high-frequency intensity signal Shi based on the high-frequency component signal Sh, and provide the high-frequency intensity signal Shi to the comparator CMP. Subsequently, the comparator CMP may generate a comparison result R based on the low-frequency intensity signal Sli and the high-frequency intensity signal Shi, and provide the comparison result R to the counter CT. Finally, the counter CT may generate a compensation setting value Vc based on the comparison result R, and provide the compensation setting value Vc to the amplifier EQ1, to adjust the high-frequency gain of the amplifier EQ1.

According to the above, the adaptive circuit 220 may reduce the power consumption of the adaptive equalizer circuit 200 and save the circuit area of the adaptive equalizer circuit 200 by the low pass filter LF. Additionally, the adaptive circuit 220 may provide the compensation setting value Vc and the feedback signal Sf to the amplifier circuit 210 based on the compensation signal Sc, to adjust the low-frequency response and the high-frequency gain of the amplifier circuit 210, thereby enhancing the compensation capability for the input signal Sin, so that the amplifier circuit 210 may provide the output signal Sout with a proportion of the high-frequency component and the low-frequency component tending to be consistent.

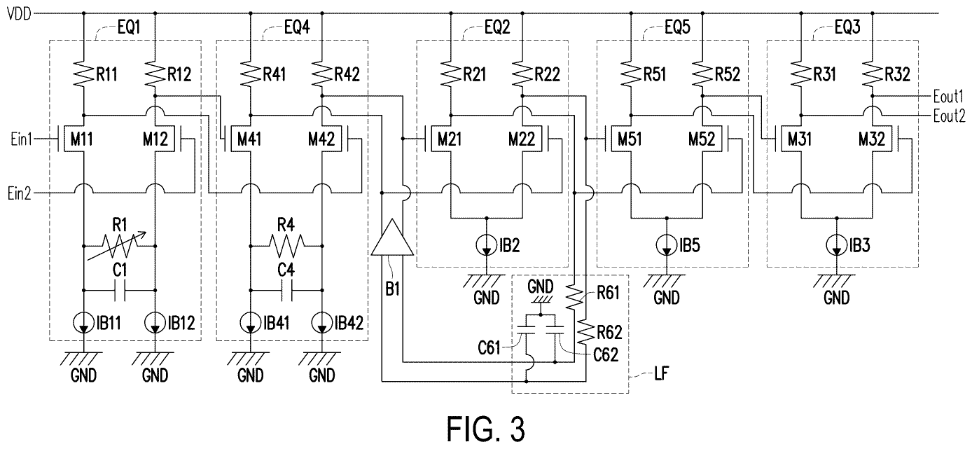

FIG. 3 illustrates a circuit diagram of an amplifier circuit, a buffer, and a low pass filter of the first embodiment of the disclosure. Please refer to FIG. 2 and FIG. 3. In this implementation, the input terminal Ein includes an input terminal Ein1 and an input terminal Ein2, and the output terminal Eout includes an output terminal Eout1 and an output terminal Eout2.

The amplifier EQ1 includes a variable resistor R1, a resistor R11, a resistor R22, a capacitor C1, a transistor M11, a transistor M12, a current source IB11, and a current source IB12. A control terminal of the transistor M11 is coupled to the input terminal Ein1. A control terminal of transistor M12 is coupled to the input terminal Ein2. The variable resistor R1 is coupled between a second terminal of the transistor M11 and a second terminal of the transistor M12. The capacitor C1 is coupled between the second terminal of the transistor M11 and the second terminal of the transistor M12. The resistor R11 is coupled between a first terminal of the transistor M11 and a reference high voltage VDD. The resistor R12 is coupled between a first terminal of the transistor M12 and the reference high voltage VDD. The current source IB11 is coupled between the second terminal of the transistor M11 and a reference low voltage GND (for example, a ground terminal). The current source IB12 is coupled between the second terminal of the transistor M12 and the reference low voltage GND.

The amplifier EQ4 is coupled between the amplifier EQ1 and the amplifier EQ2. The amplifier EQ4 includes a resistor R4, a resistor R41, a resistor R42, a capacitor C4, a transistor M41, a transistor M42, a current source IB41, and a current source IB42. A control terminal of the transistor M41 is coupled to the first terminal of the transistor M12. A control terminal of the transistor M42 is coupled to the first terminal of the transistor M11. The resistor R4 is coupled between a second terminal of the transistor M41 and a second terminal of the transistor M42. The capacitor C4 is coupled between the second terminal of the transistor M41 and the second terminal of the transistor M42. The resistor R41 is coupled between a first terminal of the transistor M41 and the reference high voltage VDD. The resistor R42 is coupled between a first terminal of the transistor M42 and the reference high voltage VDD. The current source IB41 is coupled between the second terminal of the transistor M41 and the reference low voltage GND. The current source IB42 is coupled between the second terminal of the transistor M42 and the reference low voltage GND.

The amplifier EQ2 includes a resistor R21, a resistor R22, a transistor M21, a transistor M22, and a current source IB2. The low pass filter LF includes a resistor R61, a resistor R62, a capacitor C61, and a capacitor C62. A control terminal of the transistor M21 is coupled to the first terminal of the transistor M42 and a first terminal of buffer B1. A control terminal of the transistor M22 is coupled to the first terminal of the transistor M41 and the first terminal of buffer B1. A first terminal of the transistor M21 is coupled to a first terminal of the resistor R61. A first terminal of the transistor M22 is coupled to a first terminal of the resistor R62. The capacitor C61 is coupled between a second terminal of the resistor R62, a second terminal of the buffer B1, and the reference low voltage GND. The capacitor C62 is coupled between a second terminal of the resistor R61, the second terminal of the buffer B1, and the reference low voltage GND. The resistor R21 is coupled between the first terminal of the transistor M21 and the reference high voltage VDD. The resistor R22 is coupled between the first terminal of the transistor M22 and the reference high voltage VDD. The current source IB2 is coupled between the second terminal of the transistor M21, the second terminal of the transistor M22, and the reference low voltage GND.

The amplifier EQ5 is coupled between the amplifier EQ2 and the amplifier EQ3. The amplifier EQ5 includes a resistor R51, a resistor R52, a transistor M51, a transistor M52, and a current source IB5. A control terminal of the transistor M51 is coupled to the first terminal of the transistor M22 and the first terminal of the resistor R62. A control terminal of the transistor M52 is coupled to the first terminal of the transistor M21 and the first terminal of the resistor R61. The resistor R51 is coupled between a first terminal of the transistor M51 and the reference high voltage VDD. The resistor R52 is coupled between a first terminal of the transistor M52 and the reference high voltage VDD. The current source IB5 is coupled between a second terminal of the transistor M51, a second terminal of the transistor M52, and the reference low voltage GND.

The amplifier EQ3 includes a resistor R31, a resistor R32, a transistor M31, a transistor M32, and a current source IB3. A control terminal of the transistor M31 is coupled to the first terminal of the transistor M52. A control terminal of the transistor M32 is coupled to the first terminal of the transistor M51. The resistor R31 is coupled between a first terminal of the transistor M31 and the reference high voltage VDD. The resistor R32 is coupled between a first terminal of the transistor M32 and the reference high voltage VDD. The current source IB3 is coupled between a second terminal of the transistor M31, a second terminal of the transistor M32, and the reference low voltage GND.

In this embodiment, the transistors M11, M12, M21, M22, M31, M32, M41, M42, M51, and M52 are respectively implemented as N-type field-effect transistors (FETs). In this embodiment, the transistors M11, M12, M21, M22, M31, M32, M41, M42, M51, and M52 are respectively implemented as N-type metal-oxide-semiconductor field-effect transistors (MOSFETs). In some implementations, the transistors M11, M12, M21, M22, M31, M32, M41, M42, M51, and M52 are respectively implemented as NPN-type bipolar junction transistors (BJTs).

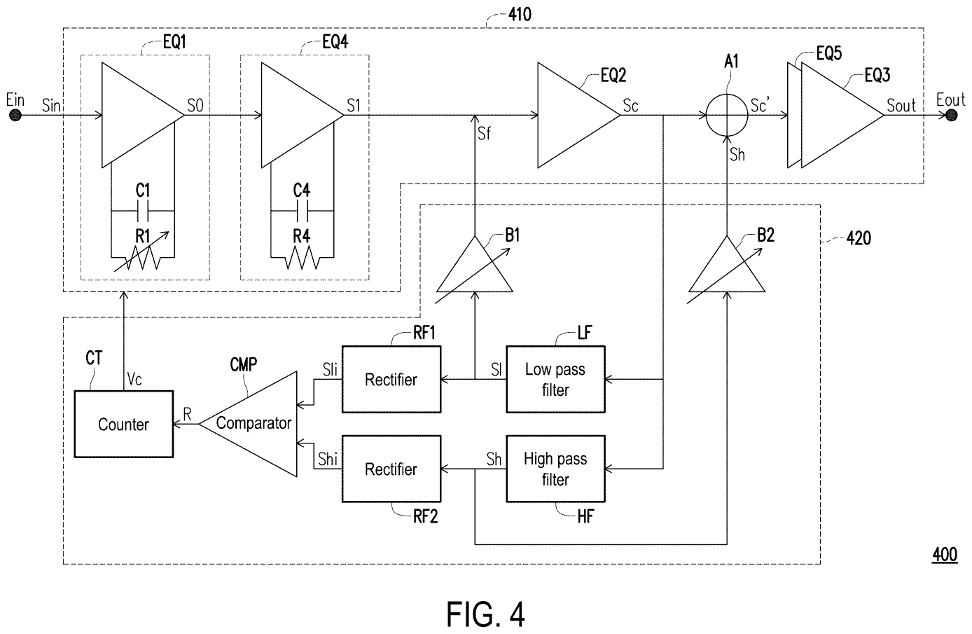

FIG. 4 illustrates a schematic diagram of an adaptive equalizer circuit according to the second embodiment of the disclosure. Please refer to FIG. 4. In this embodiment, an adaptive equalizer circuit 400 includes an input terminal Ein, an amplifier circuit 410, an adaptive circuit 420, and an output terminal Eout. The amplifier circuit 410 includes amplifiers EQ1 to EQ5 and an adder A1. The adder A1 is coupled between the amplifier EQ2 and the amplifier EQ5 (or the amplifier EQ3). The amplifiers EQ1 and EQ4 are linear equalizing amplifiers, and the amplifiers EQ2, EQ3, and EQ5 are buffer amplifiers. The number of the amplifier EQ4 and the number of the amplifier EQ5 may be designed according to actual requirements, and the disclosure does not impose any limitations. The adaptive circuit 420 includes a low pass filter LF, a high pass filter HF, a rectifier RF1, a rectifier RF2, a comparator CMP, a counter CT, a buffer B1, and a buffer B2. The buffer B2 is coupled between the high pass filter HF and the adder A1. In this embodiment, the adder A1 and the buffer B2 may be, for example, any programmable digital circuit well-known to persons skilled in the art.

In this embodiment, the adaptive circuit 420 may include a low-frequency feedback loop, an adaptation loop, and a high-frequency enhancement loop. The low-frequency feedback loop is composed of the low pass filter LF and the buffer B1. The adaptation loop is composed of the low pass filter LF, the high pass filter HF, the rectifiers RF1 and RF2, the comparator CMP, and the counter CT. The high-frequency enhancement loop is composed of the high pass filter HF and the buffer B2. In this embodiment, the low-frequency feedback loop and the adaptation loop share one low pass filter LF, and the high-frequency enhancement loop and the adaptation loop share one high pass filter HF, which may reduce the power consumption of the adaptive equalizer circuit 400 and save a circuit area of the adaptive equalizer circuit 400.

In this embodiment, the amplifier EQ1 receives an input signal Sin from the input terminal Ein. The input signal Sin is, for example, a high-speed transmission signal with severe high-frequency component loss. The amplifier EQ1 may perform high frequency compensation on the input signal Sin to generate a signal S0, and the amplifier EQ4 may perform high frequency compensation on the signal S0 to generate a signal S1. The amplifier EQ2 may perform low frequency compensation on the signal S1 to make the high-frequency component and the low-frequency component of the signal S1 more uniform, thereby generating a compensation signal Sc.

Next, the amplifier EQ2 may provide the compensation signal Sc to the low-frequency feedback loop, the adaptation loop, and the high-frequency enhancement loop of the adaptive circuit 420, to enhance the compensation capability of the adaptive equalizer circuit 400. The amplifier EQ2 may provide the compensation signal Sc to the low pass filter LF and the high pass filter HF of the adaptive circuit 420.

Reference of the implementation details of the low-frequency feedback loop and the adaptation loop may be made to the description of the low-frequency feedback loop and the adaptation loop in FIG. 2, which is not repeated here.

Regarding the high-frequency enhancement loop, the high pass filter HF may extract the high-frequency component from the compensation signal Sc to generate a high-frequency component signal Sh, and provide the high-frequency component signal Sh to the buffer B2. The buffer B2 may provide the high-frequency component signal Sh to the adder A1. Next, the adder A1 may sum the high-frequency component signal Sh with the compensation signal Sc to generate a high-frequency enhancement signal Sc′, to enhance the high-frequency component of the compensation signal Sc. Finally, the adder A1 may provide the high-frequency enhancement signal Sc′ to the amplifier EQ5, so that the amplifier EQ5 and the amplifier EQ3 may generate an output signal Sout according to the high-frequency enhancement signal Sc′, and provide the output signal Sout to the output terminal Eout.

According to the above, the adaptive circuit 420 may reduce the power consumption of the adaptive equalizer circuit 400 and save the circuit area of the adaptive equalizer circuit 400 by the low pass filter LF and the high pass filter HF. In addition, the adaptive circuit 420 may also provide a compensation setting value Vc and a feedback signal Sf to the amplifier circuit 410 based on the compensation signal Sc, to adjust the low-frequency response and high-frequency gain of the amplifier circuit 410, to enhance the compensation capability for the input signal Sin, so that the amplifier circuit 410 may provide an output signal Sout with a proportion of the high-frequency component and the low-frequency component tending to be consistent. Furthermore, the adaptive circuit 420 may also provide the high-frequency component signal Sh to the amplifier circuit 410, to enhance the high-frequency component of the output signal Sout, to respond to the situation where the high-frequency component of the input signal Sin is severely attenuated due to a transmission rate and a transmission line path.

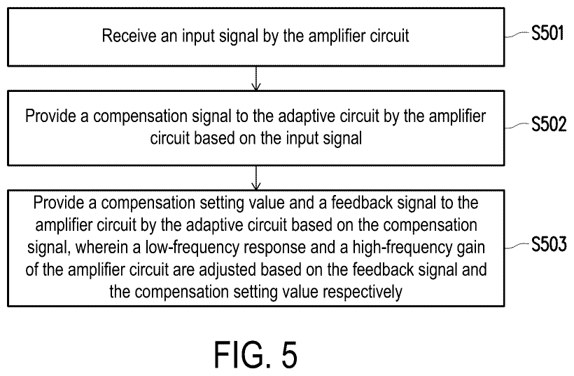

FIG. 5 illustrates a flowchart of an operation method of an adaptive equalizer circuit according to an embodiment of the disclosure. The operation method of this embodiment may be executed by the adaptive equalizer circuit 100 of FIG. 1. Please refer to FIG. 1 and FIG. 5. In Step S501, the input signal Sin is received by the amplifier circuit 110. In Step S502, the compensation signal Sc is provided to the adaptive circuit 120 by the amplifier circuit 110 based on the input signal Sin. In Step S503, the compensation setting value Vc and the feedback signal Sf are provided to the amplifier circuit 110 by the adaptive circuit 120 based on the compensation signal Sc, where the low-frequency response and the high-frequency gain of the amplifier circuit 110 are adjusted based on the feedback signal Sf and the compensation setting value Vc respectively.

The implementation details of Step S501 to Step S503 have been provided in the aforementioned embodiments, which is not repeated here.

In summary, the adaptive equalizer circuit and the operation method provided by the embodiments of the disclosure may save the power consumption and reduce the circuit area by the elements of the adaptive circuit, and enhance the compensation capability for the input signal by adjusting the low-frequency response and the high-frequency gain of the amplifier circuit continuously.

Although the disclosure has been disclosed by the above embodiments, it is not intended to limit the disclosure. Any person skilled in the art may make minor modifications and refinements without departing from the spirit and scope of the disclosure. Therefore, the protection scope of the disclosure should be defined by the appended claims.

What is claimed is:

1. An adaptive equalizer circuit, comprising:
an amplifier circuit, configured to receive an input signal; and
an adaptive circuit, coupled to the amplifier circuit, wherein the amplifier circuit provides a compensation signal to the adaptive circuit based on the input signal, and
the adaptive circuit provides a compensation setting value and a feedback signal to the amplifier circuit based on the compensation signal,
wherein a low-frequency response and a high-frequency gain of the amplifier circuit are adjusted based on the feedback signal and the compensation setting value respectively.

2. The adaptive equalizer circuit according to claim 1, further comprising:
an input terminal; and
an output terminal, wherein the amplifier circuit is coupled between the input terminal and the output terminal, and the amplifier circuit further comprises a first amplifier, a second amplifier, and a third amplifier, wherein the first amplifier is coupled between the input terminal and the second amplifier;
the second amplifier is coupled between the first amplifier and the third amplifier; and
the third amplifier is coupled between the second amplifier and the output terminal, wherein
the first amplifier receives the input signal from the input terminal,
the second amplifier provides the compensation signal to the adaptive circuit, and
the third amplifier provides an output signal to the output terminal.

3. The adaptive equalizer circuit according to claim 2, wherein
the second amplifier receives the feedback signal from the adaptive circuit, and a low-frequency response of the second amplifier is adjusted based on the feedback signal.

4. The adaptive equalizer circuit according to claim 2, wherein
the first amplifier receives the compensation setting value from the adaptive circuit, and a high-frequency gain of the first amplifier is adjusted based on the compensation setting value.

5. The adaptive equalizer circuit according to claim 2, wherein the amplifier circuit further comprises:
at least one fourth amplifier, coupled between the first amplifier and the second amplifier, wherein the at least one fourth amplifier is a linear equalizer amplifier; and
at least one fifth amplifier, coupled between the second amplifier and the third amplifier, wherein the at least one fifth amplifier is a buffer amplifier.

6. The adaptive equalizer circuit according to claim 2, wherein the adaptive circuit further comprises:
a low pass filter, coupled to the second amplifier, and configured to generate a low-frequency component signal according to the compensation signal;
a high pass filter, coupled to the second amplifier, and configured to generate a high-frequency component signal according to the compensation signal;
a first rectifier, coupled to the low pass filter, and configured to generate a low-frequency intensity signal according to the low-frequency component signal; and
a second rectifier, coupled to the high pass filter, and configured to generate a high-frequency intensity signal according to the high-frequency component signal.

7. The adaptive equalizer circuit according to claim 6, wherein the adaptive circuit further comprises:
a comparator, coupled to the first rectifier and the second rectifier, and configured to generate a comparison result according to the low-frequency intensity signal and the high-frequency intensity signal; and
a counter, coupled to the comparator, and configured to generate the compensation setting value according to the comparison result.

8. The adaptive equalizer circuit according to claim 6, wherein the adaptive circuit further comprises:
a first buffer, coupled to the low pass filter, and configured to provide the feedback signal to the second amplifier according to the low-frequency component signal.

9. The adaptive equalizer circuit according to claim 6, wherein the adaptive circuit further comprises a second buffer, and the amplifier circuit further comprises an adder, wherein
the second buffer is coupled to the high pass filter, and is configured to provide the high-frequency component signal to the adder,
the adder is coupled between the second amplifier and the third amplifier, and is configured to sum the high-frequency component signal and the compensation signal to generate a high-frequency enhancement signal, and
the third amplifier generates the output signal according to the high-frequency enhancement signal, and provides the output signal to the output terminal.

10. The adaptive equalizer circuit according to claim 2, wherein the first amplifier is a linear equalizer amplifier, and the second amplifier and the third amplifier are buffer amplifiers.

11. The adaptive equalizer circuit according to claim 2, wherein the first amplifier comprises:
a first transistor, wherein a control terminal of the first transistor is coupled to the input terminal;
a second transistor, wherein a control terminal of the second transistor is coupled to the input terminal;
a variable resistor, coupled between a second terminal of the first transistor and a second terminal of the second transistor; and
a capacitor, coupled between the second terminal of the first transistor and the second terminal of the second transistor.

12. The adaptive equalizer circuit according to claim 11, wherein the first amplifier comprises:
a first resistor, coupled between a first terminal of the first transistor and a reference high voltage;
a first current source, coupled between the second terminal of the first transistor and a reference low voltage;
a second resistor, coupled between a first terminal of the second transistor and the reference high voltage; and
a second current source, coupled between the second terminal of the second transistor and the reference low voltage.

13. The adaptive equalizer circuit according to claim 11, wherein the second amplifier comprises:
a third transistor, wherein a control terminal of the third transistor is connected to the first terminal of the second transistor, and the control terminal and a first terminal of the third transistor are coupled to the adaptive circuit;
a fourth transistor, wherein a control terminal of the fourth transistor is connected to the first terminal of the first transistor, and the control terminal and a first terminal of the fourth transistor are coupled to the adaptive circuit;
a third resistor, coupled between the first terminal of the third transistor and a reference high voltage;
a fourth resistor, coupled between the first terminal of the fourth transistor and the reference high voltage; and
a third current source, coupled between a second terminal of the third transistor, a second terminal of the fourth transistor, and a reference low voltage.

14. The adaptive equalizer circuit according to claim 13, wherein the third amplifier comprises:
a fifth transistor, wherein a control terminal of the fifth transistor is connected to the first terminal of the fourth transistor, and a first terminal of the fifth transistor is coupled to the output terminal;
a sixth transistor, wherein a control terminal of the sixth transistor is connected to the first terminal of the third transistor, and a first terminal of the sixth transistor is coupled to the output terminal;
a fifth resistor, coupled between the first terminal of the fifth transistor and the reference high voltage;
a sixth resistor, coupled between the first terminal of the sixth transistor and the reference high voltage; and
a fourth current source, coupled between a second terminal of the fifth transistor, a second terminal of the sixth transistor and the reference low voltage.

15. A operation method of an adaptive equalizer circuit, comprising:
receiving an input signal by an amplifier circuit;
providing a compensation signal to an adaptive circuit based on the input signal by the amplifier circuit; and
providing a compensation setting value and a feedback signal to the amplifier circuit based on the compensation signal by the adaptive circuit,
wherein a low-frequency response and a high-frequency gain of the amplifier circuit are adjusted based on the feedback signal and the compensation setting value respectively.
